(19) United States
(12) Patent Application Publication
(10) Pub. No.: US 2022/0112594 A1
(43) Pub. Date: Apr. 14, 2022

(54) DEVICE FOR SEALING A VACUUM CHAMBER, VACUUM PROCESSING SYSTEM, AND METHOD OF MONITORING A LOAD LOCK SEAL

(71) Applicant: Applied Materials, Inc., Santa Clara, CA (US)

(72) Inventors: Mathew Dean ALLISON, Frankfurt Am Main (DE); Andreas SAUER, Großostheim (DE)

(21) Appl. No.: 17/070,776

(22) Filed: Oct. 14, 2020

(51) Int. Cl. C23C 14/56; C23C 14/24

(52) U.S. Cl. CPC C23C 14/566; C23C 14/24

(57) ABSTRACT

A device for sealing a vacuum chamber is described, the vacuum chamber providing a first volume. The device includes an intermediate volume providing a fluid communication between the first volume and a second volume, a first seal for sealing a first conduit associated with the first volume and sealing the first volume from the intermediate volume, a second seal for sealing a second conduit associated with the second volume and sealing the second volume from the intermediate volume, and a third conduit providing a first fluid path to the intermediate volume.

### FIELD

The present disclosure relates to a device for sealing a chamber inlet or a chamber outlet, particularly for a flexible substrate. The device can be a load lock or a load lock valve. In particular, the present disclosure relates to a device for sealing a vacuum chamber, a vacuum processing apparatus, and methods of pumping and/or venting a vacuum processing apparatus.

### BACKGROUND

In many applications, it is beneficial to deposit thin layers on one or more substrates, particularly in vacuum chambers. The substrates need to be loaded into and unloaded from the vacuum chambers. A load lock valve may be provided to allow venting and pumping of one vacuum chamber while another vacuum chamber, e.g. for processing in the vacuum chamber, is maintained under vacuum. The substrate may be a flexible substrate, a web or a foil. Flexible substrates can be coated in different chambers of a flexible substrate coating apparatus. Further, a stock of a flexible substrate, for example, a roll of a flexible substrate, may be disposed in a chamber of the substrate coating apparatus. For example, the flexible substrates can be coated in a vacuum, using a vapour deposition technique, for example, physical vapour deposition or chemical vapour deposition. For maintenance or for refilling or restocking the roll of a flexible substrate, at least one of the chambers may be pressurised to atmosphere pressure, such that a person may access the chamber or the stock of a flexible substrate may be refilled or retrieved. Other chambers of the substrate coating apparatus may still remain evacuated. For these purposes, a chamber may be sealed from another chamber, in particular when the flexible substrate is traversing a wall between two chambers.

During maintenance or the like, a failure of the seal may cause a variety of problems such as, including but not limited to, danger to a maintenance personal. Further, for reactive materials to be deposited, such as lithium, a seal failure may cause additional safety issues.

Accordingly, it is beneficial to provide an improved sealing device, an improved vacuum processing system and an improved method for monitoring a load lock seal.

### SUMMARY

In the light of the above, a device for sealing a vacuum chamber, a vacuum processing system and a method of monitoring a load lock seal are provided. Further aspects, advantages and features of the present disclosure are apparent from the description and the accompanying drawings.

According to one embodiment, a device for sealing a vacuum chamber is provided, the vacuum chamber providing a first volume. The device includes an intermediate volume providing a fluid communication between the first volume and a second volume, a first seal for sealing a first conduit associated with the first volume and sealing the first volume from the intermediate volume, a second seal for sealing a second conduit associated with the second volume and sealing the second volume from the intermediate volume, and a third conduit providing a first fluid path to the intermediate volume.

According to one embodiment, a vacuum processing system for processing a substrate is provided. The vacuum processing system includes a vacuum chamber with a first wall and having a first volume, a first transfer chamber adjacent to the first wall and having a second volume; an opening at the first wall configured to transfer the substrate between the first transfer chamber and the vacuum chamber, and a sealing device at the opening for sealing the opening to isolate the first volume and the second volume with respect to each other in a closed state. The sealing device includes a first seal for sealing a first conduit, and a second seal for sealing a second conduit, and an intermediate volume between the first seal and the second seal, the intermediate volume providing a substrate transfer conduit between the first volume and the second volume at an open state of the sealing device.

According to one embodiment, a method of monitoring a load lock seal sealing a fluid communication between a first volume and a second volume is provided. The method includes closing a first seal and a second seal arranged between the first volume and the second volume, providing a first pressure in the first volume, providing a second pressure in the second volume, the second pressure being higher than the first pressure, monitoring a third pressure in an intermediate volume of the load lock seal, the intermediate volume being arranged between the first seal and the second seal and the third pressure being between the first pressure and the second pressure, and generating a seal failure alarm based upon the third pressure.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 shows a schematic view of a vacuum processing system according to embodiments described herein.

FIGS. 2A and 2B show a vacuum chamber having a device for sealing or a load lock seal, respectively, according to embodiments described herein.

FIG. 3 shows a schematic view of a load lock seal according to embodiments of the present disclosure and having a first seal, a second seal and an intermediate volume.

FIG. 4 shows schematically a cross section of a seal that may be utilized in embodiments of the present disclosure, e.g. in the device of FIG. 3.

FIG. 5 shows a flowchart of a method of activating monitoring of a sealing device according to embodiments of the present disclosure.

FIG. 6 shows a flow chart of a method of monitoring a sealing device according to embodiments of the present disclosure.

FIG. 7 shows a schematic scheme of control components for a sealing device and/or of a vacuum processing system according to embodiments of the present disclosure.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION OF THE EMBODIMENTS

Reference will now be made in detail to the various exemplary embodiments, one or more examples of which are illustrated in each figure. Each example is provided by way of explanation and is not meant as a limitation. For example, features illustrated or described as part of one embodiment can be used on or in conjunction with other embodiments to yield yet further embodiments. The intention is that the present disclosure includes such modifications and variations.

Within the following description of the drawings, the same reference numbers refer to the same components. Only the differences with respect to the individual embodiments are described. The structures shown in the drawings are not necessarily depicted true to scale but rather serve the better understanding of the embodiments.

Embodiments of the present disclosure provide a redundant load-lock seal for sealing chambers, for example, with a chamber isolating device. The leakage and/or health of the device for sealing includes a first seal and a second seal that can be monitored, particularly independently. A seal or an isolating device provided for example between two chambers, for example, a load lock chamber and a processing chamber, to isolate one vacuum chamber from the adjacent chamber is provided. The device for sealing allows vacuum to be held in one chamber while the other chamber is vented to atmosphere. The redundant design includes two seals to provide an additional level of safety in case one of the seals breaks. According to some embodiments of the present disclosure, two seals can be provided for safer isolation of chambers. Leakage monitoring provides feedback to the users, to indicate if one of the seals is failing.

With a single seal isolation, a seal failure would cause significant risks if the seal is between two chambers that are being purposefully held at different pressures. A redundant design with monitoring allows for the user to be aware of a seal failure, whilst the second seal still holds the system in a safe state. Accordingly, embodiments of the present disclosure increase safety over current designs to employees working in chambers connected to a chamber holding a vacuum. Further, a decreased risk of leakages causing dangerous and damaging environments in the process areas can be provided. A seal integrity can be tested before venting chambers and real time monitoring of seal integrity can be provided during maintenance.

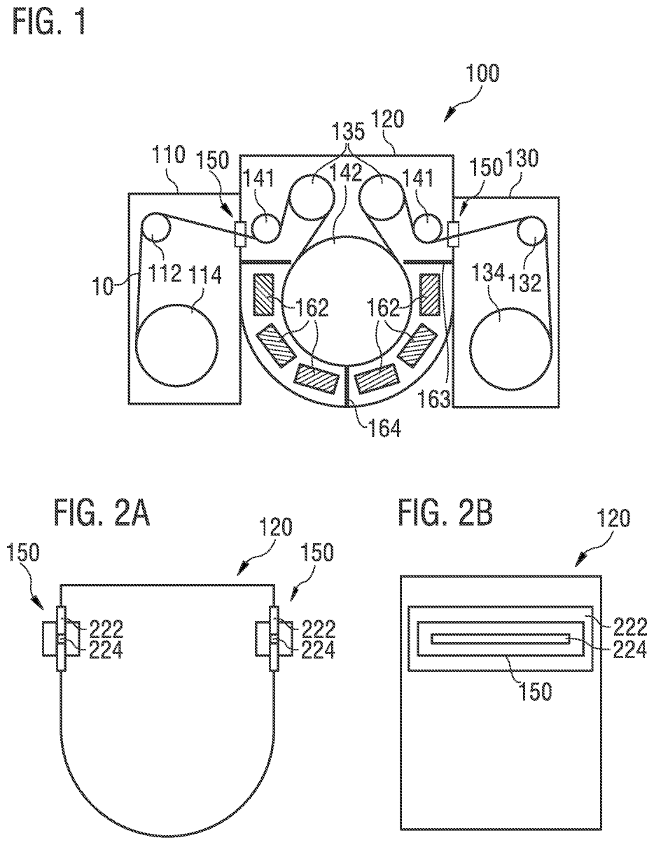

According to embodiments described herein, a vacuum processing system 100, as shown in FIG. 1, can be provided. An unwinding station 110 is provided with a roll 114 providing a flexible substrate 10. The unwinding station 110 includes a guiding roller 112. Generally, one or more guiding rollers can be provided in order to guide the substrate to a subsequent chamber, to tension the web to the appropriate tension, to control the speed of the web, or the like.

From the unwinding station 110, the flexible substrate is guided to the vacuum chamber 120, for example, a deposition chamber, and further to a winding station where the flexible substrate is wound on a roll 134 in the winding station 130. The winding station 130 can include one or more rollers 132 in order to guide the flexible substrate and to control tension, winding characteristics, or the like. One or more of the chambers used in the vacuum processing system, as for example shown in FIG. 1 can include a plurality of guiding rollers (see e.g. reference numerals 112, 132, or 141) to guide the flexible substrate to the deposition areas and to control the transport of the web.

From the unwinding station 110, the substrate 10 is guided to the vacuum chamber 120. Guiding rollers 141 are provided to guide the substrate on a drum 142. The drum 142 can be a cooling drum such that the substrate 10 can be cooled while guided over the drum 142 and while deposited in the vacuum chamber 120. As shown in FIG. 1, a gas separation member 163 can be provided such that the deposition region and the region in which the rollers 135 are provided are separated.

With respect to FIG. 1, reference is made to an unwinding station 110 and a winding station 130. Accordingly, a substrate transport direction from left to right in FIG. 1 is described. According to some embodiments, also a substrate transport direction from right to left in FIG. 1 can be provided. Accordingly, the winding station 130 shown in FIG. 1 may function as an unwinding station and the unwinding station 110 shown in FIG. 1 may function as a winding station. In the following, reference is made to a winding station, wherein the winding station can be utilized for providing a roll of unprocessed substrate material or for providing a spool receiving the processed substrate material.

As shown in FIG. 1, deposition sources 162 can be provided for depositing material on the substrate, particularly while the substrate is supported by the drum 142. According to yet further embodiments, which can be combined with other embodiments described herein, other substrate processing devices can be provided and the vacuum processing system 100 can be utilized for substrate processing in general. For example, the improved load lock seal concept may also be applicable for substrates being wafers or large area substrates for display manufacturing or the like.

According to some embodiments, which can be combined with other embodiments described herein, one or more deposition sources 162 can be an evaporation source or an evaporation source assembly. An evaporation source assembly can be configured to provide evaporated material towards a substrate 10. The evaporation source assembly can be provided in the vacuum chamber 120 or can at least partially be provided in the vacuum chamber 120. The evaporation source assembly may be disposed along the substrate transportation direction for providing material to the substrate.

According to embodiments that can be combined with any other embodiment described herein, the evaporation source assembly may provide material to be deposited to the substrate. The evaporation source assembly may include one or more crucibles where the material to be deposited may be evaporated by providing a temperature to the material suitable to evaporate the material. For example, the material to be deposited can include, for example, metal, in particular lithium, metal alloys, and other vaporizable materials or the like which have a gaseous phase under given conditions. According to yet further embodiments, additionally or alternatively, the material may include magnesium (Mg), ytterbium (Yb) and lithium fluoride (LiF).

According to some embodiments, which can be combined with other embodiments described herein, a material layer may be deposited on a substrate comprising at least one of copper or graphite. A substrate may include a copper foil to generate an anode of a battery. Further, a layer including graphite and at least one of silicon and a silicon oxide may be provided on a thin web or foil. The web or foil may further include a conductive layer or may consist of a conductive layer serving as a contact surface of the anode.

As described above, the vacuum processing system can be a system for depositing reactive materials on a substrate, particularly materials reactive under atmospheric conditions. A decreased risk of leakages causing dangerous and damaging environments in the process areas can be provided. A seal integrity can be tested before venting chambers and real time monitoring of seal integrity can be provided during maintenance. According to embodiments of the present disclosure, a device for sealing adjacent vacuum chambers may also be provided for substrate processing in general. Embodiments of the present disclosure provide a redundant load-lock seal for sealing chambers, for example, with a chamber isolating device. The leakage and/or health of the device for sealing including a first seal and a second seal can be monitored, particularly independently. Accordingly, embodiments of the present disclosure increase safety over current designs to employees working in chambers connected to a chamber holding a vacuum.

According to embodiments of the present disclosure, a vacuum processing system 100 may include a device for sealing a vacuum chamber, for example a sealing device 150. According to some embodiments, which can be combined with other embodiments described herein, the sealing device can be provided between the vacuum chamber providing a first volume, for example, the vacuum chamber 120 including the deposition sources 162 and a second volume. A second volume may be a volume of a neighboring vacuum chamber. FIG. 1 shows a sealing device 150 between the unwinding station 110 and the vacuum chamber 120 and shows a sealing device 150 between the vacuum chamber 120 and the winding station 130. According to yet further embodiments, the second volume may be the volume of a load lock vacuum chamber. A load lock vacuum chamber can be frequently vented and evacuated for loading and/or unloading of substrates into a vacuum chamber. According to yet further embodiments, the second volume may be a surrounding of the vacuum chamber 120, i.e. an atmospheric region outside the vacuum chamber.

FIGS. 2A and 2B show different schematic side views of a vacuum chamber 120 which is used as a platform for a vacuum processing system and which can enclose different substrate guiding systems and different deposition units or deposition unit assemblies. The chamber 120 has flanges 222 with openings 224 on opposing sides thereof. During operation, a substrate, for example, a flexible substrate, can enter and exit the vacuum chamber 120 from a neighboring chamber through the openings 224. The flanges 222 can be used to seal the vacuum chamber 120 with respect to an outer atmosphere and connect one vacuum chamber 120 to a neighboring chamber such that the vacuum processing systems can be evacuated. Sealing devices 150 can be provided at one side or both sides of the vacuum chamber 120. According to some embodiments, which can be combined with other embodiments described herein, sealing devices according to the present disclosure can be used for vacuum chambers, particularly neighboring vacuum chambers, wherein one chamber may be at atmospheric pressure for some operating conditions and the adjacent chamber is at vacuum conditions. For example, a vacuum chamber may be at atmospheric pressure during maintenance or during loading and unloading of a substrate. For example, a winding station according to embodiments of the present disclosure may be at atmospheric pressure during exchanging of a roll 114 of flexible substrate, either a roll with a new substrate or a roll with the processed substrate.

A flexible substrate or web as used within the embodiments described herein can be characterized in that the flexible substrate is bendable. The term “web” may be synonymously used to describe the term “strip” or the term “flexible substrate”. For instance, the web as described in embodiments herein may be a foil as described above. According to some embodiments, which can be combined with other embodiments described herein, a flexible substrate or a web can be provided in a vacuum processing system 100 on a roll 114.

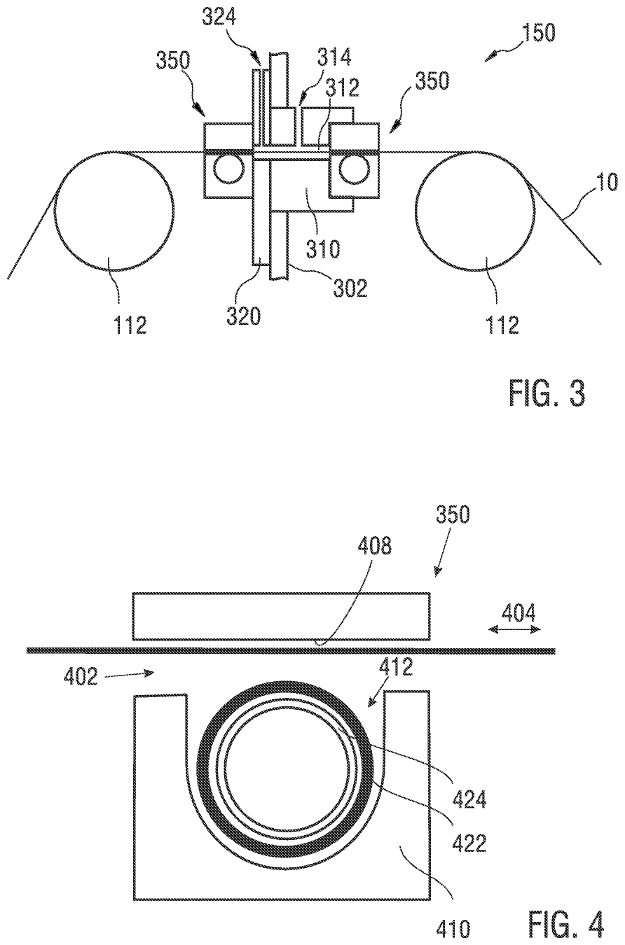

FIG. 3 shows a sealing device 150, i.e. a device for sealing a vacuum chamber. The substrate 10 is guided by rollers 112 through an opening of a vacuum chamber. For example, the opening can be an opening 224 as shown in FIG. 2A. FIG. 3 shows a portion of the wall 302 of the vacuum chamber. The sealing device 150 includes a first seal 350 and a second seal 350. According to some embodiments, which can be combined with other embodiments described herein, the first seal and the second seal may have a similar functionality. For example, a seal 350 as explained in more detail with respect to FIG. 4 can be used for the sealing device 150.

The sealing device 150 includes a device body 310. A first volume according to embodiments of the present disclosure can be provided on one side of the first seal, for example, the right-hand side in FIG. 3. The first volume can be a volume of a vacuum chamber, for example, a vacuum chamber 120 shown in FIG. 1. A second volume according to embodiments of the present disclosure can be provided on a side of the second seal, for example, the left-hand side in FIG. 3. The second volume can be the volume of a winding station, for example, the unwinding station 110 shown in FIG. 1. The first volume and the second volume are provided on opposite sides of the wall 302 of the vacuum chamber.

The device body includes an intermediate volume 312. The intermediate volume can be sealed by the first seal and the second seal. A first conduit providing a fluid communication between the first volume and the intermediate volume can be sealed by the first seal. A second conduit providing a fluid communication between the second volume and the intermediate volume can be sealed by the second seal. According to embodiments of the present disclosure, at least a third conduit 314 can be provided. The third conduit 314 can be an opening in the device body 310. Alternatively, the third conduit can be provided in the sealing plate 320 of the sealing device 150.

The third conduit provides a first fluid path for the intermediate volume 312. The third conduit is in fluid communication with the intermediate volume while one or both of the first seal and the second seal are closed. For example, the third conduit can be connected to a pressure gauge or pressure sensor to monitor the pressure in the intermediate volume, particularly to monitor the pressure in the intermediate volume irrespective of whether or not the first seal and the second seal are closed. Accordingly, the fluid path of the third conduit is not influenced by the first seal and the second seal, respectively. According to yet further embodiments, which can be combined with other embodiments described herein, the third conduit may further be connected to a vacuum pump to evacuate the intermediate volume, particularly irrespective of whether or not the first seal and the second seal are opened or closed.

According to some embodiments, which can be combined with other embodiments described herein, a fourth conduit 324 can be provided. The force conduit can provide a second fluid path for the intermediate volume 312. The fourth conduit 324 is provided in the sealing plate 320 in the example illustrated in FIG. 3. Alternatively, the fourth conduit can be provided in the device body 310. According to some embodiments, which can be combined with other embodiments described herein, the third conduit 314 can be provided in the device body 310 or the sealing plate 320. Further, the fourth conduit 324 can be provided in the device body or the sealing plate 320. According to some embodiments, which can be combined with other embodiments described herein, the third conduit and the fourth conduit can be provided in the sealing plate. A guiding of the conduits via or through the second volume may be beneficial. A valve can be coupled to the fourth conduit to connect the fourth conduit with a gas conduit to pressurize the intermediate volume. For example, the gas conduit can be connected to an argon tank to provide argon to the intermediate volume. According to embodiments of the present disclosure, the third conduit and the fourth conduit connect the intermediate volume to one or more of a valve, a pressure gauge (or pressure sensor), a vacuum pump, and a gas tank. The intermediate volume is connected irrespective of the state of the first valve and the second valve.

According to some embodiments, which can be combined with other embodiments described herein, the first seal and/or the second seal may have some leakage even when fully functional. The pressure may rise slightly in the intermediate volume when both seals are closed based on the acceptable leakage. Accordingly, a conduit is provided for evacuation and for a gas inlet, e.g. an argon inlet, which allows to repeatedly pump down the intermediate volume and re-pressurize with argon (or another gas) to control the pressure.

As shown in FIG. 3, the first seal 350 may be attached to the device body 310. For example, the first seal can be attached to the device body with screws or other fixation elements and a seal can be provided between the first seal 350 and the device body 310. The device body 310 can be attached to the sealing plate 320. A seal can be provided between the device body 310 and the sealing plate 320. The second seal 350 can be attached to the sealing plate 320. Accordingly, the first seal, the second seal, and the device body are attached to the sealing plate 320. The first seal, the second seal and the device body can be attached to the sealing plate 320 directly or indirectly, for example, via the sealing body. The sealing plate 320 can be attached to the wall 302 of the vacuum chamber to seal the opening of the vacuum chamber with respect to a neighboring vacuum chamber or with respect to another second volume. The sealing device 150 can be detached from the vacuum chamber as one arrangement of at least the first seal, the second seal, and the device body. Accordingly, the sealing device can be easily exchanged during maintenance.

According to one embodiment, a device for sealing a vacuum chamber is provided. The vacuum chamber provides a first volume. The first volume and a second volume can be sealed off or isolated with the sealing device with respect to each other. The sealing device includes an intermediate volume providing a fluid communication between the first volume and the second volume. A first seal for sealing a first conduit adjacent to the first volume and for sealing the first volume from an intermediate volume is provided. A second seal for sealing a second conduit adjacent to the second volume and for sealing the second volume from the intermediate volume is provided. The sealing device includes a third conduit providing a first fluid path from at least one of the first volume and the second volume to the intermediate volume.

According to some embodiments, which can be combined with other embodiments described herein, the sealing device includes a fourth conduit providing a second fluid path from at least one of the first volume and the second volume to the intermediate volume. For example, the fourth conduit can be utilized to pressurize the intermediate volume. According to some embodiments, the device can include a valve coupled to a gas conduit to pressurize the intermediate volume or to control the pressure in the intermediate volume. Yet further, additionally or alternatively, the sealing device can include a pressure gauge or pressure sensor coupled to the third conduit to monitor the pressure in the intermediate volume.

According to some embodiments, which can be combined with other embodiments described herein, the sealing device can include a device body including at least a portion of the intermediate volume, wherein at least one of the first seal and the second seal can be coupled to the device body. Further, a sealing plate configured to be attached to the vacuum chamber to mount the device to the vacuum chamber can be provided for some embodiments, which can be combined with other embodiments described herein. At least one of the device body, the first seal and the second seal can be coupled to the sealing plate. According to some embodiments of the present disclosure, which can be combined with other embodiments of the present disclosure, the intermediate volume is a small volume as compared to the first volume of a vacuum chamber. The intermediate volume can be 30 L or less.

With single seal isolation, a seal failure would cause significant risks if the seal is between two chambers or volumes that are being held at different pressures. A redundant design with a first seal and a second seal and with monitoring by one or more of the third conduit and the fourth conduit allows for the user to be aware of a seal failure, whilst the second seal still holds the system in a safe state.

Accordingly, for maintenance or loading of a substrate, one chamber in a system may be vented whilst another chamber next to it is held at vacuum. With a single seal isolation, a seal failure would cause a safety risk for people working in the vented chamber, a risk of damage to material in the process area, and a potential chemical and combustion risk associated with atmosphere flooding into the process area.

A sealing device 150 as described in the present disclosure can increase safety to employees working in chambers connected to a chamber holding a vacuum. Further, there can be a decreased risk of leakages causing dangerous and damaging environments in the process areas.

As described in more detail below, the sealing device according to embodiments of the present disclosure provides the capability to test seal integrity before venting chambers and real time monitoring of seal integrity during maintenance.

A sealing device according to embodiments of the present disclosure provides a redundant design uses two seals, which, when closed, form a sealed volume, i.e. an intermediate volume between the two seals.

FIG. 4. shows schematically a cross section of a seal 350 that can be utilized for embodiments of the present disclosure. The seal 350 includes a body 410 having a substrate opening 402 which is traversed by the flexible substrate 10 in a transport direction 404 of the flexible substrate. In some embodiments, which may be combined with other embodiments disclosed herein, the body 410 is manufactured from a rigid material, for example, a metal, such as steel or stainless steel. The substrate opening 402 has a sealing surface 408, extending along the longitudinal direction of the seal 350. Opposite the sealing surface 408, a groove or a recess 412 is disposed.

In the recess 412, an elastic tube 422 is arranged. The elastic tube 422 may be manufactured from rubber, viton, silicone, and/or nitrile butadiene rubber (NBR). The elastic tube may be inflated, such that a portion of the surface of the elastic tube 422 is pressed against the sealing surface 408. In the case where the flexible substrate 10 is traversing the substrate opening 402, the inflated elastic tube is pressed against the flexible substrate 10. The elastic tube may have an outer diameter between about 25 mm and about 50 mm, in particular, between 30 mm and 45 mm in a deflated state. Further, a deflated elastic tube may have a thickness between 2 mm and about 8 mm, in particular between about 3 mm and about 7 mm. In some embodiments, which may be combined with other embodiments disclosed herein, the elastic tube 422 may be inflated by a pressure source.

According to some embodiments, the recess 412 is substantially U-shaped in a traversal cross-section, such that the inflated elastic tube 422 may press tightly against the wall of the recess 412. In another embodiment, the recess 412 may be substantially half-circular or half-oval shaped in a traversal cross-section. The radius of the half circular portion of the recess may exceed about 10% or less of the outer radius of the deflated elastic tube. Alternatively, the deflated elastic tube may be in contact with the wall of the recess.

A rigid tube 424 can be disposed within the elastic tube 422 as exemplarily shown in FIG. 4. The rigid tube 424 may have at least the length of the substrate opening 402 in the axial direction of the elastic tube 422, i.e. perpendicular to the paper plane in FIG. 4. For example, the rigid tube may have an outer diameter being slightly smaller, for example 5% to 20% smaller, than the inner diameter of the deflated elastic tube. A space is formed between the deflated elastic tube and the rigid tube. In an embodiment, the rigid tube 424 is maintained in a fixed position in the recess 412 of the seal 350. The elastic tube 422 is maintained by the rigid tube in a fixed position in the seal. Thus, even in a deflated state, the elastic tube retracts into or in the direction of the recess, such that the deflated elastic tube 422 may not harm a flexible substrate 10 traversing the substrate opening 402. A deflated elastic tube may not scratch the flexible substrate.

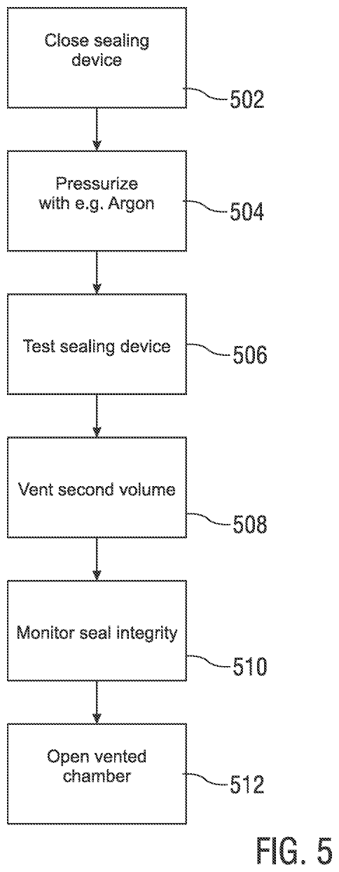

FIG. 5 shows a method of activating a monitoring of the load lock valves, i.e. of a sealing device according to embodiments described herein. For example, if a change of substrate, such as a roll of a flexible substrate, or maintenance in chamber is needed, the sealing device can be closed as illustrated in operation 502. The first seal and the second seal are closed. The intermediate volume can be pressurized at operation 504. For example, argon or another gas can be introduced via the fourth conduit into the intermediate area (see, for example, intermediate volume 312 in FIG. 3).

After the sealing device has been closed, the vacuum can be maintained in the first volume and the second volume. For example, the vacuum in the vacuum chamber 120 in FIG. 1 and the unwinding station 110 in FIG. 1 can be maintained. Pressurizing the intermediate volume or the intermediate area, for example, with argon, results in a higher pressure in the intermediate volume as compared to the first volume and the second volume. At operation 506, the sealing device can be tested by monitoring at least one of the pressures in the first volume and the second volume. Additionally or alternatively, an argon detector can be operated to monitor the argon concentration in the first volume and the second volume. If the first seal is malfunctioning, the pressure in the first volume increases and/or argon flows from the intermediate volume to the first volume and may be detected in the first volume. If the second seal is malfunctioning, the pressure in the second volume increases and/or argon flows from the intermediate volume to the second volume and may be detected in the second volume. Accordingly, the two seals of the sealing device can be tested for leakage.

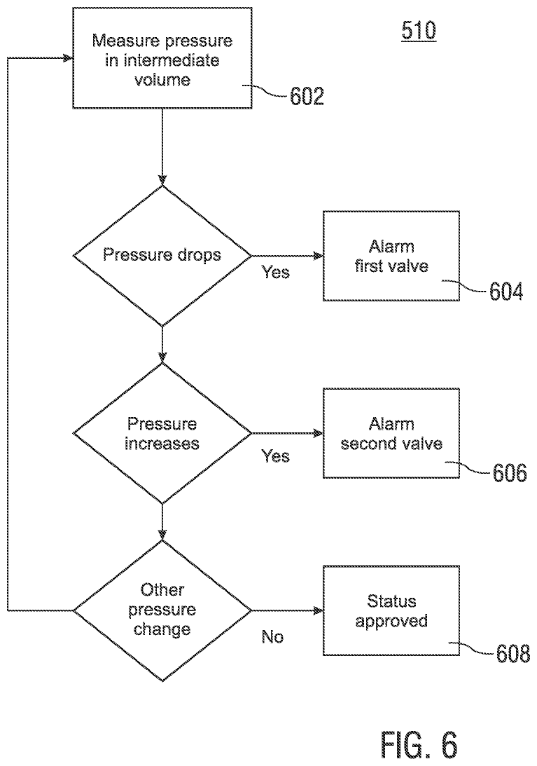

Upon a successful test of the sealing device, the second volume, for example the unwinding station 110, can be vented. This is illustrated by operation 508. Yet further, at operation 510, the seal integrity of the first seal and the second seal can be monitored after venting of the second volume. Monitoring the seal integrity according to operation 510 is described in more detail with respect to FIG. 6. If the seal integrity has been confirmed, i.e. the status of the sealing device is approved to be in order, the vented chamber, for example, the chamber providing the vented second volume, can be opened at operation 512. Maintenance or substrate exchange, for example, exchange of the roll of a flexible substrate, can be provided.

As described above, FIG. 5 illustrates the method of activating a load lock valve according to embodiments of the present disclosure. Similarly, the load lock valves may be activated, for example, after maintenance and or substrate change has been completed. The chamber enclosing the second volume can be closed and can be pumped down to the pressure, i.e., a vacuum, for operation of the vacuum processing system. After maintenance and/or substrate exchange, the first valve and the second valve of the sealing device are closed. Similar to the testing operation 506 described with respect to FIG. 5, the sealing device can be tested for leakage after evacuating the chamber enclosing the second volume. Upon a successful test of the sealing device, the load locks can be opened and monitoring may stop. The vacuum processing of a substrate can be continued.

FIG. 6 illustrates monitoring of the seal integrity of the seals of the sealing device according to operation 510 shown in FIG. 5. The first seal and the second seal of the sealing device, for example, a load lock valve according to embodiments of the present disclosure, can be monitored while the vacuum chamber enclosing the first volume is evacuated and the vacuum chamber enclosing the second volume is vented. Accordingly, a low pressure (vacuum) is provided in the first volume and atmospheric pressure is provided in the second volume. The first seal is closed and the second seal is closed. The intermediate volume is pressurized with a pressure between the first pressure in the first volume and the second pressure in the second volume. The pressure in the intermediate volume can be monitored (see operation 602), for example, with a pressure gauge. If the pressure in the intermediate volume drops, i.e. the pressure reduces, the first valve between the first volume and the intermediate volume may have a leakage. Accordingly, upon the pressure drop, an alarm for the integrity of the first valve of the sealing device can be provided according to operation 604. If the pressure in the intermediate volume rises, i.e. the pressure increases, the second valve between the second volume and the intermediate volume may have a leakage. Accordingly, upon a pressure increase, an alarm for the integrity of the second valve of the sealing device can be provided according to operation 606. For both cases, i.e. an alarm for the first valve and the second valve, the integrity of the respective other valve is still given. Embodiments of the present disclosure may monitor the state of the load-lock seals of the sealing device when one vacuum chamber is vented, for example, when the winding chamber is vented during roll change or maintenance.

According to some embodiments, which can be combined with other embodiments of the present disclosure, the pressure change resulting in an alarm according to operation 604 or an alarm according to operation 606 can be provided by a pressure threshold. Additionally or alternatively, one or both alarms may be triggered by a threshold for a pressure variation, particularly a variation of the pressure within a predetermined time.

According to some modifications, a pressure change monitoring in the intermediate volume may be below a threshold for triggering an alarm. In the event of an acceptable leakage or an acceptable pressure change, i.e. there is no other pressure change outside normal operation conditions, the integrity status of the sealing device can be approved as shown at operation 608. Particularly, the integrity of the first seal and the second seal can be approved. According to some embodiments, which can be combined with other embodiments described herein, as illustrated in FIG. 6, the routine may be repeated, for example, every one to five minutes, or another with another appropriate frequency to continuously monitor the integrity of the seals of the sealing device.

According to one embodiment, a method of monitoring a load lock seal or a sealing device, particularly a sealing device according to embodiments of the present disclosure, includes closing a first seal and a second seal arranged between the first volume and the second volume. A first pressure is provided in the first volume and a second pressure is provided in the second volume, wherein the second pressure is higher than the first pressure. A third pressure in an intermediate volume of the load lock seal is monitored, wherein the intermediate volume is arranged between the first seal and the second seal. The third pressure is between the first pressure and the second pressure. A seal failure alarm is provided based upon the third pressure. According to some embodiments, which can be combined with other embodiments described herein, the seal failure alarm indicates a failure of the first seal in the event the third pressure drops below a first failure threshold or a pressure variation of the third pressure drops below a first variation threshold or wherein the seal failure alarm indicates a failure of the second seal in the event the third pressure raises a second failure threshold or the pressure variation rises above a second variation threshold.

According to some embodiments, which can be combined with other embodiments described herein, the intermediate volume can be filled with argon at the third pressure. Argon concentration may be measured to further improve the monitoring of the integrity of the sealing device. According to yet further embodiments, which can be combined with other embodiments described herein, methods according to embodiments of the present disclosure may further include at least one of: measuring the pressure in the first volume; measuring the pressure in the second volume; detecting argon in the first volume; and detecting argon in the second volume.

As described above, the pressure in the space between the seals, i.e. in the intermediate volume, can be provided to a pressure value in between the pressures of the two modules, i.e. neighboring chambers or volumes. According to some embodiments, which can be combined with other embodiments described herein, the first pressure in the first volume can be below 10⁻³ mbar, such as in the range of 10⁻⁵ mbar, the second pressure in the second volume can be atmospheric pressure or above 100 mbar, and the third pressure in the intermediate volume can be between 0.1 mbar and 100 mbar, e.g. about 20 mbar.

The space or intermediate volume isolates the modules or chambers from each other. The pressure between the seals is monitored. If the pressure rises, there is a leak at the seal on the side of the module with the higher pressure. If the pressure falls, there is a leak at the seal on the side of the module with the lower pressure. The monitored redundant design allows for the user to be aware of a seal failure, with reduced risk to the health of the operator or of a process failure, as the second seal still holds the system in a safe state.

According to some embodiments, as described under operation 506 in FIG. 5, the sealing device can also be tested before allowing one of the chambers to be vented. The seals are closed and the pressure in the space between the seals is increased. If a pressure rise is detected in one of the chambers and/or argon is detected in one of the chambers, the seal on the side of said chamber is faulty. The state of the load-lock seals can be tested before allowing to vent and open a chamber, such as a winding chamber.

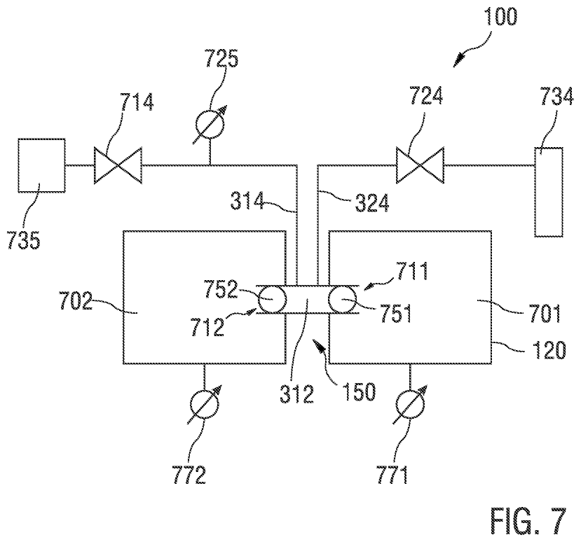

FIG. 7 shows a schematic view of a vacuum processing system 100 and illustrates the components for controlling and monitoring the integrity of a sealing device. The first volume 701, for example, the volume of the vacuum chamber 120 is in fluid communication with a second volume 702 via the intermediate volume 312. A first valve 751 is provided between the first volume 701 and the intermediate volume 312. The first valve 751 can be opened or closed. A second valve 752 is provided between the second volume 702 and the intermediate volume 312. The second valve 752 can be opened or closed. The sealing device 150 isolating the first volume and the second volume from each other includes the first valve, the second valve and the intermediate volume between the first valve and the second valve. A first pressure gauge 771 is in fluid communication with the first volume to measure the pressure in the vacuum chamber 120. A second pressure gauge 772 is in fluid communication with the second volume 702 to measure the pressure in the vacuum chamber corresponding to the second volume 702 or a surrounding area defining the second volume 702.

The first valve 751 is provided in a first conduit 711 adjacent to the first volume 701 or associated with the first volume 701. The second valve 752 is provided in a second conduit 712 adjacent to the second volume 702 or associated with the second volume 702. The first volume and the second volume are in fluid communication via the first conduit, the intermediate volume and the second conduit.

A third conduit 314 is provided at the intermediate volume 312. The third conduit is connected to a pressure gauge 725. The measurement in the intermediate volume can be measured for monitoring the integrity of the sealing device according to embodiments of the present disclosure. Further, the third valve 714 can be provided for the third conduit 314. The third valve 714 may open or close a connection to vacuum pump 735. The vacuum pump 735 can evacuate the pressure in the intermediate volume 312. Accordingly, the pressure in the intermediate volume can be adjusted for monitoring the integrity of the seals of the sealing device.

The fourth conduit 324 is connected to a pressure line or a gas tank 734, particularly via the fourth valve 724. Accordingly, the intermediate volume 312 can be filled with a gas, for example, argon or another gas, such as air, dried air or another inert gas, through the fourth conduit 324. According to some embodiments, which can be combined with other embodiments described herein, one or more of a pressure controller, such as a pressure gauge or pressure sensor, and a flow monitor can be provided to record and/or control the pressure in the intermediate chamber.

According to one embodiment, a vacuum processing system for processing a substrate is provided. The vacuum processing system includes a vacuum chamber with a first wall and having a first volume. A first transfer chamber adjacent to the first wall and having a second volume can be provided. For example, the first transfer chamber can be a chamber of an unwinding station 110 shown in FIG. 1 or can be another vacuum chamber. The first transfer chamber may also be a further processing chamber through which a substrate is transferred. An opening is included at the first wall and is configured to transfer the substrate between the first transfer chamber and the vacuum chamber. The vacuum processing system includes a sealing device at the opening for sealing the opening to isolate the first volume and the second volume with respect to each other in a closed state. The sealing device includes a first seal for sealing a first conduit and second seal for sealing a second conduit. The sealing device further includes an intermediate volume between the first seal and the second seal, wherein the intermediate volume provides a substrate transfer conduit between the first volume and the second volume at an open state of the sealing device. According to some embodiments, which can be combined with other embodiments described herein, the vacuum processing system may further include a third conduit providing a first fluid path being guided through or passing through at least one of the first volume and the second volume to the intermediate volume. The sealing device can be a sealing device or load lock valve according to any of the embodiments of the present disclosure. According to some embodiments, which can be combined with other embodiments described herein, a further transfer chamber, for example, such as the chamber of the winding station 130 shown in FIG. 1, can be provided. Further devices for sealing according to embodiments of the present disclosure can be provided, particularly a load lock valve between the vacuum chamber and the second transfer chamber.

According to yet further embodiments, the seal integrity can be tested while the first volume and the second volume are at atmospheric conditions. The intermediate area or the intermediate volume between the first valve and the second valve can be evacuated and a pressure increase that may result from a seal failure of the first valve or the second valve can be detected. Yet further, argon can be provided at the first volume or the second volume and argon concentration can be measured in the intermediate area or the intermediate volume. Accordingly, it can be determined which of the first seal and the second seal is faulty.

Embodiments of the present disclosure allow for one or more of the following advantages. A sealing device between adjacent vacuum chambers can be provided with the redundant design including a first seal and a second seal to reduce the risk in case of a seal failure. Further, the seal integrity of the seals of the sealing device can be mounted in various operating conditions as described above.

A device for sealing a vacuum chamber, the vacuum chamber providing a first volume, comprising: an intermediate volume providing a fluid communication between the first volume and a second volume; a first seal for sealing a first conduit associated with the first volume and sealing the first volume from the intermediate volume; a second seal for sealing a second conduit associated with the second volume and sealing the second volume from the intermediate volume; and a third conduit providing a first fluid path to the intermediate volume.

The device according to claim 1, further comprising: a fourth conduit providing a second fluid path to the intermediate volume.

The device according to claim 2, further comprising: a valve coupled to a gas conduit to pressurize the intermediate volume.

The device according to any of claims 1 to 3, further comprising: a pressure gauge or pressure sensor coupled to the third conduit to monitor a pressure in the intermediate volume.

The device according to any of claims 1 to 4, further comprising: a device body including at least a portion of the intermediate volume, wherein at least one of the first seal and the second seal is coupled to the device body.

The device according to claim 5, further comprising: a sealing plate configured to be attached to the vacuum chamber to mount the device to the vacuum chamber, wherein at least one of the device body, the first seal and the second seal is coupled to the sealing plate.

The device according to any of claims 1 to 6, wherein the intermediate volume is 30 l or less.

A vacuum processing system for processing a substrate, comprising: a vacuum chamber with a first wall and having a first volume; a first transfer chamber adjacent to the first wall and having a second volume; an opening at the first wall configured to transfer the substrate between the first transfer chamber and the vacuum chamber; and a sealing device at the opening for sealing the opening to isolate the first volume and the second volume with respect to each other in a closed state, the sealing device comprising: a first seal for sealing a first conduit; a second seal for sealing a second conduit; and an intermediate volume between the first seal and the second seal, the intermediate volume providing a substrate transfer conduit between the first volume and the second volume at an open state of the sealing device.

The vacuum processing system according to claim 8, wherein the sealing device further comprises: a third conduit providing a first fluid path passing through at least one of the first volume and the second volume to the intermediate volume.

The vacuum processing system according to any of claims 8 to 9, wherein the sealing device is a device according to any of claims 1 to 7.

The vacuum processing system according to any of claims 8 to 10, further comprising: a second transfer chamber adjacent to the vacuum chamber; and a further device for sealing according to any of claims 1 to 7 provided as a load lock valve between the vacuum chamber and the second transfer chamber.

A method of monitoring a load lock seal sealing a fluid communication between a first volume and a second volume, comprising: closing a first seal and a second seal arranged between the first volume and the second volume; providing a first pressure in the first volume; providing a second pressure in the second volume, the second pressure being higher than the first pressure; monitoring a third pressure in an intermediate volume of the load lock seal, the intermediate volume being arranged between the first seal and the second seal and the third pressure being between the first pressure and the second pressure; and generating a seal failure alarm based upon the third pressure.

The method of claim 12, wherein the seal failure alarm indicates a failure of the first seal if the third pressure drops below a first failure threshold or a pressure variation of the third pressure drops below a first variation threshold, or wherein the seal failure alarm indicates a failure of the second seal if the third pressure raises a second failure threshold or the pressure variation rises above a second variation threshold.

The method of any of claims 12 to 13, wherein the intermediate volume is filled with argon at the third pressure.

The method of any of claims 12 to 14, further comprising at least one of: measuring a pressure in the first volume; measuring a pressure in the second volume; detecting argon in the first volume; and detecting argon in the second volume.

While the foregoing is directed to some embodiments, other and further embodiments may be devised without departing from the basic scope thereof, and the scope thereof is determined by the claims that follow.

1. A device for sealing a vacuum chamber, the vacuum chamber providing a first volume, comprising:
an intermediate volume providing a fluid communication between the first volume and a second volume;
a first seal for sealing a first conduit associated with the first volume and sealing the first volume from the intermediate volume;
a second seal for sealing a second conduit associated with the second volume and sealing the second volume from the intermediate volume; and
a third conduit providing a first fluid path to the intermediate volume.

2. The device of claim 1, further comprising:
a fourth conduit providing a second fluid path to the intermediate volume.

3. The device of claim 2, further comprising:
a valve coupled to a gas conduit to pressurize the intermediate volume.

4. The device of claim 1, further comprising:
a pressure gauge or pressure sensor coupled to the third conduit to monitor a pressure in the intermediate volume.

5. The device of claim 1, further comprising:
a device body including at least a portion of the intermediate volume, wherein at least one of the first seal and the second seal is coupled to the device body.

6. The device of claim 5, further comprising:
a sealing plate configured to be attached to the vacuum chamber to mount the device to the vacuum chamber, wherein at least one of the device body, the first seal and the second seal is coupled to the sealing plate.

7. The device of claim 1, wherein the intermediate volume is 30 l or less.

8. A vacuum processing system for processing a substrate, comprising:
a vacuum chamber with a first wall and having a first volume;
a first transfer chamber adjacent to the first wall and having a second volume;
an opening at the first wall configured to transfer the substrate between the first transfer chamber and the vacuum chamber; and
a sealing device at the opening for sealing the opening to isolate the first volume and the second volume with respect to each other in a closed state, the sealing device comprising:
a first seal for sealing a first conduit;
a second seal for sealing a second conduit; and
an intermediate volume between the first seal and the second seal, the intermediate volume providing a substrate transfer conduit between the first volume and the second volume at an open state of the sealing device.

9. The vacuum processing system of claim 8, wherein the sealing device further comprises:
a third conduit providing a first fluid path passing through at least one of the first volume and the second volume to the intermediate volume.

10. The vacuum processing system of claim 8, wherein the sealing device is a device according to claim 1.

11. The vacuum processing system of claim 8, further comprising:
a second transfer chamber adjacent to the vacuum chamber; and
a further device for sealing according to claim 1 provided as a load lock valve between the vacuum chamber and the second transfer chamber.

12. A method of monitoring a load lock seal sealing a fluid communication between a first volume and a second volume, comprising:
closing a first seal and a second seal arranged between the first volume and the second volume;
providing a first pressure in the first volume;
providing a second pressure in the second volume, the second pressure being higher than the first pressure;
monitoring a third pressure in an intermediate volume of the load lock seal, the intermediate volume being arranged between the first seal and the second seal and the third pressure being between the first pressure and the second pressure; and
generating a seal failure alarm based upon the third pressure.

13. The method of claim 12, wherein the seal failure alarm indicates a failure of the first seal if the third pressure drops below a first failure threshold or a pressure variation of the third pressure drops below a first variation threshold, or wherein the seal failure alarm indicates a failure of the second seal if the third pressure raises a second failure threshold or the pressure variation rises above a second variation threshold.

14. The method of claim 12, wherein the intermediate volume is filled with argon at the third pressure.

15. The method of claim 12, further comprising at least one of:
measuring a pressure in the first volume;
measuring a pressure in the second volume;
detecting argon in the first volume; and
detecting argon in the second volume.
